(19) United States
(12) Patent Application Publication
(10) Pub. No.: US 2024/0334712 A1
(43) Pub. Date: Oct. 3, 2024

(54) MEMORY CELL BASED ON A PHASE-CHANGE MATERIAL

(71) Applicant: STMicroelectronics International N.V., Geneva (CH)

(72) Inventor: Daniel BENOIT, Grenoble (FR)

(73) Assignee: STMicroelectronics International N.V., Geneva (CH)

(21) Appl. No.: 18/616,924

(22) Filed: Mar. 26, 2024

(30) Foreign Application Priority Data
Mar. 30, 2023 (FR) 2303064

(51) Int. Cl. H10B 63/10

(52) U.S. Cl. CPC H10B 63/10

(57) ABSTRACT

A memory cell comprising a stack of a conductive via, of a layer made of a phase-change material, and of a first electrode, the memory cell being covered with an encapsulation layer made of a silicon nitride having a density or volumic mass smaller than 2.2 g/cm³. A method of manufacturing a memory cell and a system having an integrated memory circuit that includes a plurality of memory cells is also provided.

This application claims the priority benefit of French patent application number FR2303064, filed on Mar. 30, 2023, entitled “Cellule mémoire à base d'un matériau à changement de phase,” which is hereby incorporated by reference to the maximum extent allowable by law.

### TECHNICAL FIELD

The present disclosure concerns non-volatile memories and phase-change memories (or PCMs) and their structure.

### DESCRIPTION OF THE RELATED ART

Phase-change memories (or PCMs) are non-volatile memories using the properties of phase-change materials. A phase-change material is a material having the ability to change crystalline state under the effect of heat, and more particularly to switch between a crystalline state and an amorphous state, more strongly resistive than the crystalline state. Phase-change memories take advantage of the fact that the electric resistances of the amorphous phase of phase-change materials and those of the crystalline phase are different in order to store data.

There exists a need to improve electronic devices comprising a memory circuit comprising memory cells based on a phase-change material, and their manufacturing methods.

### BRIEF SUMMARY

An embodiment of the present disclosure overcomes all or part of the disadvantages of known memory cells.

An embodiment of the present disclosure provides a memory cell comprising a stack of a conductive via, of a layer made of a phase-change material, and of a second electrode, the memory cell being covered with an encapsulation layer made of a silicon nitride having a density or volumic mass smaller than 2.2 g/cm³.

In one embodiment, the encapsulation layer may cover the sides of the layer made of the phase-change material and of the second electrode.

In one embodiment, the encapsulation layer has a density or volumic mass smaller than 2.15 g/cm³.

In one embodiment, the phase-change material is a chalcogenide.

In one embodiment, the phase-change material is an alloy of germanium, antimony, and tellurium.

In one embodiment, the memory cell comprises, between the layer made of the phase-change material and the first electrode, a heating element surrounded with an insulating layer.

In one embodiment, the encapsulation layer has a thickness in the range from 5 nm to 80 nm.

Another embodiment provides a method of manufacturing a memory cell which may be summarized as including:
the forming of a stack of a conductive via, of a layer made of a phase-change material, and of a second electrode,
the deposition of an encapsulation layer made of a silicon nitride having a density or volumic mass smaller than 2.2 g/cm³.

In one embodiment, the deposition of the encapsulation layer may be performed by pulsed plasma enhanced chemical vapor deposition.

Another embodiment provides an integrated memory circuit that includes a plurality of memory cells such as described.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings.

FIG. 1 illustrates a partial and simplified cross-section view of an embodiment of a memory cell.

### DETAILED DESCRIPTION

Like features have been designated by like references in the various figures. In particular, the structural and functional features that are common among the various embodiments may have the same references and may dispose identical structural, dimensional and material properties.

For the sake of clarity, only the steps and elements that are useful for the understanding of the described embodiments have been illustrated and described in detail. In particular, the electric connections between memory cells organized in an array and of the selection circuits forming the memory circuit have not been described in detail, the described embodiments being compatible with usual selection circuits as well as their corresponding addressing circuits.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings.

Unless specified otherwise, the expressions “about,” “approximately,” “substantially,” and “in the order of” signify plus or minus 10%, preferably of plus or minus 5%.

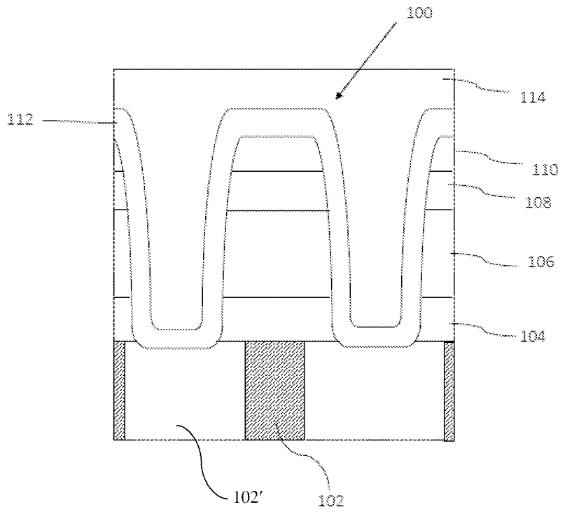

FIG. 1 illustrates a partial and simplified cross-section view of an embodiment of a memory cell 100.

The memory cell 100 is, for example, intended to be used in memory circuits, for example, integrated memories in the automobile field.

In FIG. 1, the memory cell 100 has been entirely shown and two memory cells 100 have been partly shown. It should be noted that these memory cells 100 form part of a large number of memory cells 100 manufactured by using thin-film layers of phase-change materials, resistive materials, insulating materials, conductive materials, etc.

For simplification, reference will be made to layers to designate the corresponding elements of a stack forming the single memory cell 100. It should however be understood that the corresponding layers correspond, in practice, to thin films deposited and etched to form individual memory elements separated by insulating trenches and arranged, for example, in the form of an array of word lines and of bit lines. As an example, the three cells 100 shown in FIG. 1 are cells 100 of a same word line.

The memory cell 100 comprises a stack comprising, in the order, a conductive via 102, an insulating layer 104, surrounding a heating element (not shown in FIG. 1), a layer made of a phase-change material 106 or PCM, and an upper electrode 108. As an example, the memory cell 100 further comprises, in the stack, a protection layer 110, on the upper surface of the upper electrode 108.

The upper electrode 108 and the conductive via 102 of each memory cell 100 may be interconnected, for example, in rows and in columns. As an example, the upper electrode 108 is connected to the bit line of the memory cell 100. The conductive via 102 may be connected to the word line of the memory cell 100.

As an example, the upper electrode 108 may extend over the surface of a plurality of memory cells 100 of a same bit line without being singulated. Similarly, the conductive via 102 may extend over the surface of a plurality of memory cells 100 of a same word line without being singulated.

The upper electrode 108 and the conductive via 102 are, for example, made of a refractory metal or refractory metal nitride, such as carbon (C), a carbon nitride ((CN)n), titanium (Ti), titanium nitride (TiN), silicon titanium nitride (TiSiN), tungsten (W), a tungsten nitride (W2N, WN, WN2), carbon tungsten nitride, silicon tungsten nitride, tantalum (Ta), tantalum nitride (TaN), silicon tantalum nitride, tantalum tungsten, or any alloy or combination of these materials. The upper electrode 108 is, for example, made of titanium nitride. As an example, the upper electrode 108 has a thickness in the range from 5 nm to 70 nm, for example, in the range from 15 nm to 30 nm, for example, in the order of 20 nm. The upper electrode 108 covers, and is for example in contact by its lower surface with, the upper surface of the PCM layer 106.

The conductive vias 102 are, for example, separated by an insulating layer 102′. The insulating layer 104, for example, covers the upper surface of the conductive vias 102 separated by the insulating layer 102′ and is, for example, in contact with the conductive vias 102 and the insulating layer 102′. The insulating layer 104, for example, does not continuously extend over the upper surface of the plurality of memory cells 100. The insulating layer 104 is, for example, singulated within each memory cell 100. The insulating layer 104 is, for example, made of a material enabling to limit thermal dissipations originating from the heating element. The insulating layer 104 is, for example, made of silicon oxide (SiO₂) or of silicon nitride (SiN). The heating element surrounded with the insulating layer 104 extends, for example, from the upper surface of the conductive via 102 to the lower surface of the PCM layer 106. As an example, the heating element is in contact, on the one hand, with the conductive via 102 and on the other hand, with the PCM layer 106. Each heating element is “fully confined,” which means that the heating element of each cell is separated from the heating elements of the adjacent memory cells 100 by the insulating layer 104.

The PCM layer 106 covers, and is for example in contact by its lower surface with, the upper surface of the insulating layer 104. The PCM layer 106 is made of a material which has the ability to switch from a resistive state, generally amorphous, to a less resistive state, that is to a lightly-resistive state, generally crystalline, and this, by the heating of this material by the underlying heating element. The high resistivity state may be associated with a reset state “reset” or with a logic value “0,” while a low resistivity state may be associated with a state of setting to one “set,” or with a logic value “1.”

The PCM layer 106 is, for example, made of any phase-change material such as phase-change chalcogenides. For example, the PCM layer 106 is made of germanium (Ge), of antimony (Sb), of tellurium (Te), or of any alloy made of all or some of these compounds. The PCM layer 106 has, for example, a thickness in the range from 10 nm to 100 nm, for example in the range from 40 nm to 60 nm.

The protection layer 110, for example, corresponds to residuals of a masking layer enabling to etch the underlying layers. The protection layer 110 is, for example, formed on the underlying layers, while they extend over the entire wafer. The protection layer 110 is then locally removed to form a hard mask used as an etch mask for the stack of the upper electrode 108, of the PCM layer 106, and of the insulating layer 104. The etching of this stack enables, for example, to form the bits lines of the array of the memory cells 100. The protection layer 110 is, for example, made of a nitride, for example of silicon nitride. The protection layer 110, at the end of the above-mentioned etch step, may remain with a thickness smaller than 70 nm, for example smaller than 40 nm, for example in the order of 20 nm.

At the end of the forming of the memory cell 100, the stack comprising layers 104, 106, the upper electrode layer 108, and the protection layer 110, is covered by an encapsulation layer 112. As an example, the encapsulation layer 112 enables protection of the PCM layer 106 from oxidation. The encapsulation layer 112 more precisely covers the sides of the layers 104, 106, 110 and of the upper electrode 108 as well as the upper surface of the protection layer 110. As an example, the encapsulation layer 112 is in contact with the sides of the PCM layer 106. In the shown example, the encapsulation layer 112 is in contact with the sides of the layers 104, 106, 110 and of the upper electrode 108 as well as the upper surface of the protection layer 110.

The encapsulation layer 112 is made of silicon nitride.

In one embodiment, the silicon nitride of the encapsulation layer 112 has a density smaller than 2.2, for example smaller than 2.15. The density here corresponds to the volumic mass of the material expressed in g/cm³, divided by a reference volumic mass here equal to 1 g/cm³. The encapsulation layer 112 thus has a volumic mass smaller than 2.2 g/cm³, for example smaller than 2.15 g/cm³.

The encapsulation layer 112, for example, has a substantially uniform thickness. The thickness of the encapsulation layer 112 is, for example, in the range from 5 nm to 80 nm, for example in the range from 10 nm to 30 nm, for example in the order of 17 nm. The encapsulation layer 112 is, for example, deposited by a plasma-enhanced chemical vapor deposition or PECVD method. As an example, the encapsulation layer 112 is deposited by pulsed plasma, that is, the plasma is ignited by successive pulses enabling to deposit a layer of small density, here smaller than 2.2. As an example, during this deposition step, the plasma, for example, comprises between 300 and 3,000 pulses per second, for example in the order of 1,000 pulses per second.

For a more uniform deposition of the encapsulation layer 112 in terms of thickness and a better adhesion of this same layer to the side of the stack, a precursor may be used. As an example, the precursor is trisilylamine (H₉NSi₃).

As an example, at the end of the forming of the memory cells 100 covered with the encapsulation layer 112, the structure may be covered with an insulating material 114, separating and insulating the memory cells 100 and more precisely, the bit lines of memory cells 100. The insulating material 114 is, for example, made of an oxide.

Memory cells 100 are likely to be used in devices capable of undergoing strong temperature rises, for example higher than 100° C. This phenomenon is independent from the programming of memory cells 100 during which the PCM layer 106 is heated via the heating element present in the insulating layer 104. To keep a good reliability of the device, it is important for the resistivity of the PCM layer 106, programmed in logic state “1,” to remain constant with the general temperature increase of the device.

It has been observed that the density of the material of the encapsulation layer 112 has an influence on the variation of the resistivity of the PCM layer 106 when the device undergoes a temperature increase.

Indeed, for memory cells 100 for which the material of their encapsulation layer 112 has a density in the order of 2.35, the resistivity of the PCM layer 106 programmed prior to state “set” is practically multiplied by 4 when the device is heated for one hour at approximately 230° C. This figure, for example, decreases to 2.5 when the material of the encapsulation layer 112 has a density in the order of 2.29 and, for example, to 1.6 when the material of the encapsulation layer 112 has a density in the order of 2.11, in the same time and temperature conditions and for the same nature of material for the encapsulation layer 112.

An advantage of the present embodiment is that the density smaller than 2.2 of the encapsulation layer 112 enables each memory cell 100 with a better temperature stability and thus a better manufacturing efficiency and a greater reliability.

Various embodiments and variants have been described. Those skilled in the art will understand that certain features of these various embodiments and variants may be combined, and other variants will occur to those skilled in the art. In particular, the embodiments are not limited to the examples of numerical values nor to the examples of materials mentioned in the present disclosure.

Finally, the practical implementation of the described embodiments and variants is within the abilities of those skilled in the art based on the functional indications given hereabove.

A memory cell (100) may be summarized as including a stack of a conductive via (102), of a layer made of a phase-change material (106), and of a second electrode (108), the memory cell (100) being covered with an encapsulation layer (112) made of a silicon nitride having a density or volumic mass smaller than 2.2 g/cm³.

The encapsulation layer (112) may cover the sides of the layer made of the phase-change material (106) and of the second electrode (108).

The encapsulation layer (112) may have a density or volumic mass smaller than 2.15 g/cm³.

The phase-change material may be a chalcogenide.

The phase-change material may be an alloy of germanium, antimony, and tellurium.

The memory cell (100) may include, between the layer made of the phase-change material and the first electrode, a heating element surrounded with an insulating layer (104).

The encapsulation layer may have a thickness in the range from 5 nm to 80 nm.

A method of manufacturing a memory cell (100) may be summarized as including: the forming of a stack of a conductive via (102), of a layer made of a phase-change material (106), and of a second electrode (108), and the deposition of an encapsulation layer (112) made of a silicon nitride having a density or volumic mass smaller than 2.2 g/cm³.

The deposition of the encapsulation layer may be performed by pulsed plasma enhanced chemical vapor deposition.

An integrated memory circuit may be summarized as including a plurality of memory cells.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A memory cell comprising:
a stack of layers;
a conductive via coupled to the stack;
a layer made of a phase-change material;
a first electrode; and
an encapsulation layer made of a silicon nitride having a density smaller than 2.2 g/cm³.

2. The memory cell according to claim 1, wherein the encapsulation layer covers sides of the layer made of the phase-change material and of the first electrode.

3. The memory cell according to claim 1, wherein the encapsulation layer has a density smaller than 2.15 g/cm³.

4. The memory cell according to claim 1, wherein the phase-change material is a chalcogenide.

5. The memory cell according to claim 4, wherein the phase-change material is an alloy of germanium, antimony, and tellurium.

6. The memory cell according to claim 1, further comprising, between the layer made of the phase-change material and the first electrode, a heating element surrounded with an insulating layer.

7. The memory cell according to claim 1, wherein the encapsulation layer has a thickness in the range from 5 nm to 80 nm.

8. A method of manufacturing a memory cell comprising:
forming a conductive via couled to a stack of layers;
forming a layer of a phase-change material, and of a first electrode; and
forming an encapsulation layer made of a silicon nitride having a density smaller than 2.2 g/cm³.

9. The method according to claim 8, wherein the deposition of the encapsulation layer is performed by pulsed plasma enhanced chemical vapor deposition.

10. A device, comprising:
an integrated memory circuit that includes:
a plurality of memory cells, wherein each memory cell includes a stack layers and a conductive via coupled to the stack of layers, the stack of layers including:
a layer made of a phase-change material;
a first electrode; and
an encapsulation layer made of a silicon nitride having a density smaller than 2.2 g/cm³.

11. The device of claim 10, wherein the encapsulation layer covers sides of the layer made of the phase-change material and of the first electrode.

12. The device of claim 10, wherein the encapsulation layer has a density smaller than 2.15 g/cm³.

13. The device of claim 10, wherein the phase-change material is a chalcogenide.

14. The device of claim 13, wherein the phase-change material is an alloy of germanium, antimony, and tellurium.

15. The device of claim 10, further comprising, between the layer made of the phase-change material and the first electrode, a heating element surrounded with an insulating layer.

16. The device of claim 10, wherein the encapsulation layer has a thickness in the range from 5 nm to 80 nm.
